(19) United States
(12) Patent Application Publication
(10) Pub. No.: US 2005/0244570 A1
(43) Pub. Date: Nov. 3, 2005

(54) Deposition thickness measuring method, material layer forming method, deposition thickness measuring apparatus, and material layer forming apparatus

(76) Inventors: Kenji Tanase, Mizuho-shi (JP); Hiroki Ishida, Anpachi-gun (JP)

Correspondence Address: CANTOR COLBURN, LLP, 55 GRIFFIN ROAD SOUTH, BLOOMFIELD, CT, 06002, US

(21) Appl. No.: 11/071,276

(22) Filed: Mar. 3, 2005

(30) Foreign Application Priority Data
Mar. 3, 2004 (JP) 2004-59236
Feb. 25, 2005 (JP) 2005-50123
Feb. 25, 2005 (JP) 2005-50124

(51) Int. Cl. C23C 16/00

(52) U.S. Cl. 427/10; 118/688; 427/248.1

(57) ABSTRACT

Light emitted from a light emitting device is irradiated onto a film thickness monitoring region and the light conveyed from the monitoring region is detected by a light receiving device. The light emitting device and the light receiving device may be provided within the film forming chamber. The absorption intensity or fluorescence intensity or X ray intensity or the reflection rate at the monitoring region which is formed on a portion of the substrate from the same material as the material layer at the time of deposition is detected based on data from the light receiving device. A controller then controls the transporting rate of a deposition source and/or the heating state of a heater to adjust the deposition rate, whereby a material layer having a desired thickness is formed on the substrate.

### CROSS-REFERENCE TO RELATED APPLICATIONS

The entire disclosure of Japanese Patent Applications Nos. 2004-59236, 2005-50123, and 2005-50124 including specification, claims, drawings and abstract is incorporated herein by reference.

### BACKGROUND OF THE INVENTION

1. Field of the Invention

The present invention relates to deposition of a material on a substrate and measurement of the deposition thickness.

2. Description of Related Art

Conventionally, a layered structure formed by a plurality of material layers has been used in various types of devices, and techniques such as evaporation and sputtering are used for deposition of the layers. For example, organic electroluminescence (EL) displays include pixels each including an organic EL element (OLED) arranged in a matrix for achieving display. A known type of organic EL element includes, between an anode and a cathode, an organic layer including a hole transport layer, an emissive layer, an electron transport layer, and so on. The technique of forming such an organic layer using vacuum evaporation is described, for example, in Japanese Patent Laid-Open Publication No. 2003-257644.

In the organic EL display as described above, the thickness of each organic layer is extremely thin compared to an electrode layer or the like, and a plurality of organic layers are often accumulated in a layered structure. Accordingly, it is expected that the thickness of a layer significantly affects the light emission characteristics, and therefore appropriate deposition of each layer is desired. It is therefore demanded that the thickness of each layer be accurate.

Further, in manufacturing of organic EL displays, it is more efficient to use as large a substrate as possible. When so-called small-size displays such as 1-inch to 10-inch type displays are to be manufactured, it is preferable to form a number of these display regions simultaneously on a mother substrate and then cut and separate the individual displays after they are manufactured. In this case, an organic material is also to be deposited on the substrate having a relatively large area to form organic layers. Accordingly, it is also demanded that a variation in these organic layers be minimized among different deposition positions on the substrate.

Here, spectroscopic ellipsometers and thickness meters using a quartz oscillator are used for measuring the thickness of a thin film. The spectroscopic ellipsometer is used for measuring the thickness of a sample which has been formed, outside the film forming device, and therefore cannot measure the thickness while the film is actually being formed. In addition, the spectroscopic ellipsometer requires a high degree of smoothness for a film surface to be measured, and therefore cannot provide highly precise measurement when measuring the thickness of an organic layer for use in display, which often has an uneven surface caused by an element such as a thin film transistor, for example, formed below the organic EL element.

On the other hand, with a method of measuring a film thickness (a deposition amount) by a change in the number of oscillations of a quartz oscillator, it is possible to dispose the quartz oscillator within a film forming device for measuring the thickness of a material adhered to the quartz oscillator. This method, however, cannot provide stable measurement because the measurement values vary after continuous use of the quartz oscillator. In addition, the quartz oscillator cannot measure the thickness of a material layer which is actually formed on a substrate.

### SUMMARY OF THE INVENTION

It is therefore an advantage of the present invention to effectively measure a thickness of a film during deposition of a film material and to effectively control the deposition in accordance with the measured value.

In one aspect, the present invention provides a method of measuring a deposition thickness of a material layer which is deposited on a substrate, comprising the steps of depositing a material onto a substrate and a deposition thickness monitoring region provided at a predetermined position on or near the substrate to form a material layer; irradiating predetermined light onto the deposition thickness monitoring region and detecting light conveyed from the material layer at the deposition thickness monitoring region; and measuring the deposition thickness of the material layer formed on the substrate based on the intensity of the light which is detected.

In accordance with another aspect, the present invention provides a method of forming a material layer on a substrate, comprising the steps of depositing a material onto a substrate and a deposition thickness monitoring region provided at a predetermined position on or near the substrate to form a material layer; irradiating predetermined light onto the deposition thickness monitoring region and detecting light conveyed from the material layer at the deposition thickness monitoring region; and measuring the deposition thickness of the material layer formed on the substrate based on the intensity of the light which is detected and controlling a deposition rate of the material in accordance with the measurement result.

In accordance with still another aspect of the present invention, the depositing of the material is performed by an evaporation method in which the material in an evaporation source is heated and evaporated to be deposited on the substrate, and at least one of a heating state of the material and a relative scanning rate of the evaporation source and the substrate is controlled to control the deposition rate.

In accordance with a further aspect of the present invention, a plurality of deposition thickness monitoring regions are provided on the substrate or near the substrate such that they are separate from each other, and heating distribution of the evaporation source is controlled based on the deposition thickness at each deposition thickness monitoring region.

In accordance with another aspect of the present invention, the deposition thickness of the material layer is preferably obtained by detecting the absorption intensity, the fluorescence intensity, or the reflection intensity, based on the light conveyed from the deposition thickness monitoring region. In this case, the light conveyed from the material layer which is obtained by irradiating light onto the deposition thickness monitoring region is transmitted light, reflected light, or emissive light (fluorescent light or the like).

In accordance with another aspect of the present invention, a forming apparatus for forming a material layer by deposition on a substrate comprises a light irradiation device for irradiating predetermined light onto a deposition thickness monitoring region provided at a predetermined position on or near a substrate on which a material layer is deposited; a light detecting device for detecting the intensity of light transmitted from the deposition thickness monitoring region onto which light is irradiated; and a deposition rate controller for measuring the deposition thickness of the material layer based on the intensity of light detected by the light detecting device and adjusting a deposition rate based on the result of measurement of the deposition thickness.

In accordance with a further aspect of the present invention, a method of measuring a deposition thickness of a material layer on a substrate comprises the steps of depositing a material onto a substrate and a deposition thickness monitoring region provided at a predetermined position on or near the substrate to form a material layer, irradiating ultraviolet rays or visible light onto the deposition thickness monitoring region and detecting light conveyed from the material layer at the deposition thickness monitoring region, and measuring the deposition thickness of the material layer formed on the substrate based on the intensity of the light which is detected.

In still another aspect of the present invention, a method of measuring a deposition thickness of a material layer on a substrate, comprises the steps of depositing a material onto a substrate and a deposition thickness monitoring region provided at a predetermined position on or near the substrate to form a material layer, irradiating an X ray onto the deposition thickness monitoring region and detecting a reflection wave from the material layer at the deposition thickness monitoring region, and measuring the deposition thickness of the material layer formed on the substrate based on the reflection wave which is detected.

As described above, according to the present invention, the deposition thickness of a material layer is obtained based on the absorption intensity or the fluorescent light intensity or the reflection rate, or further interference of light by detecting the light which is irradiated onto and conveyed from the deposition thickness monitoring region. By detecting the deposition thickness of an actual material layer such as an evaporation layer from the intensity or interference of light as described above, the film thickness can be obtained with high accuracy during formation of the material layer. It is therefore possible to control the deposition conditions (such as the temperature or the transporting rate of the evaporation source) in accordance with the detected deposition thickness to thereby form a material layer having an appropriate thickness. Further, because the thickness is measured simultaneously with formation of the material layer, i.e. the thickness is monitored during formation of the material layer, the time required for measuring the deposition thickness can be drastically shortened compared to a method in which thickness measurement is performed in a separate step outside the film forming apparatus. In addition, with regard to a process substrate on which the deposition value becomes significantly varied from the target value, it is possible to adjust the deposition thickness at this point or remove such a substrate from the process, thus promoting manufacturing efficiency.

### BRIEF DESCRIPTION OF THE DRAWINGS

Preferred embodiments of the present invention will be described in detail based on the following drawings, wherein:

FIG. 1 shows an overall structure of an apparatus for performing evaporation;

FIG. 2A schematically shows an apparatus structure for thickness measurement by measuring X ray reflectivity;

FIG. 2B schematically shows an apparatus structure for thickness measurement by measuring X ray reflection;

FIG. 2C is a view for explaining a difference in the optical paths which is caused depending on a film thickness when X rays are used for measurement;

FIG. 2D is conceptual view showing an oscillation structure in the X ray reflectivity;

FIG. 3 is a graph showing a relationship between a film thickness measured from absorption intensity and a film thickness obtained by actual measurement using a contact-type step device;

FIG. 4 is a view showing an example dummy substrate used for thickness measurement, which is disposed along with a substrate;

FIG. 5 is a view showing monitoring portions on a substrate;

FIG. 6 shows an example structure in which a film thickness measurement mechanism of the present embodiment is applied in a vertical type evaporation apparatus; and

FIG. 7 shows an example structure in which a film thickness measurement mechanism of the present embodiment is applied in a film forming apparatus which uses a shower nozzle.

### DETAILED DESCRIPTION OF PREFERRED EMBODIMENTS

Preferred embodiments of the present invention will be described in detail with reference to the drawings.

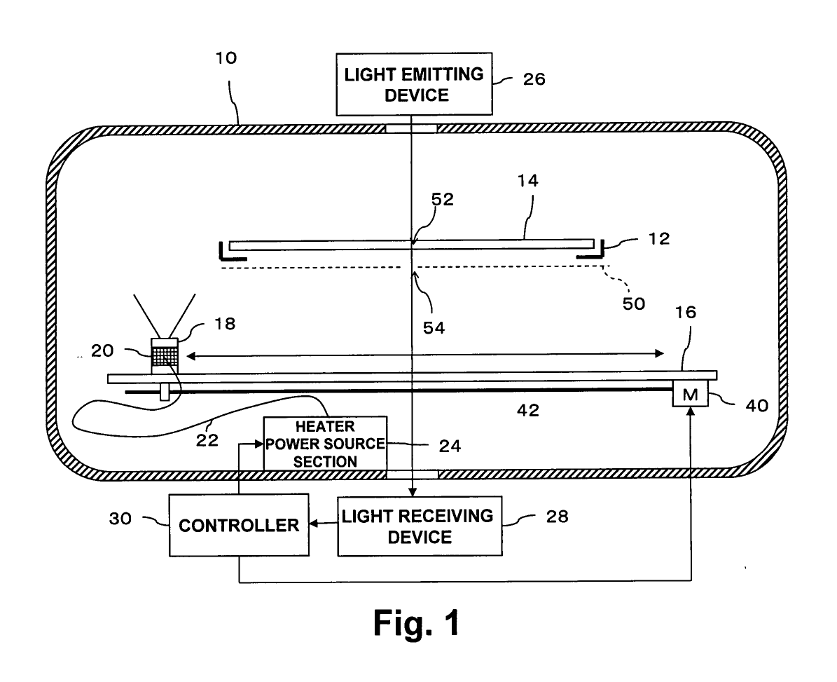

FIG. 1 schematically shows a structure of a deposition apparatus (evaporation apparatus) according to one embodiment of the present invention. A vacuum chamber (a film forming chamber) 10 is configured air-tightly, and the interior of the vacuum chamber 10, after a substrate (e.g. a glass substrate) 14 which is a deposition object is introduced therein, is kept in a predetermined decompressed state by means of a vacuum pump or the like. A substrate fixing section 12 is provided at the upper portion within the vacuum chamber 10 and the substrate 14 is fixed to the substrate fixing section 12. Further, a crucible transporting rail 16 is disposed under the substrate 14 which is thus fixed, and a crucible 18 is provided on the crucible transporting rail 16 in a reciprocatable manner. While transport of the crucible 18 is basically achieved by a motor 40, any of other various types of power transmission method may be appropriately adopted. In the shown example, the motor 40 rotates a continuous thread 42 and the rotation of the continuous thread 42 then controls transport of the crucible 18. Here, it is required that the transporting means move at a fixed rate so as to achieve uniform deposition.

The crucible 18 is an elongated box-shape evaporation source (a linear source) which extends slightly longer than the width of the substrate 14, for example, and heats and evaporates an evaporation material contained in the crucible 18, which is then discharged through an opening at the upper part of the crucible 18. The evaporation material thus discharged adheres to the lower surface of the substrate 14 where it is deposited. By moving (scanning) the crucible 18 in the longitudinal direction of the substrate 14, a material layer can be formed by evaporation over the entire surface of the substrate 14 under substantially the same conditions. While in the shown example only a single crucible 18 is provided, a plurality of crucibles 18 may be provided for evaporating a material from each crucible 18. In this case, it is possible to evaporate different materials from the plurality of crucibles 18 to form a layered structure of different materials.

When a material layer is to be formed by evaporation only on a predetermined portion on the substrate, a mask 50 is disposed on the lower surface of the substrate 14 to thereby limit the evaporation portion, as shown in FIG. 1. For example, when an organic EL element including an emissive layer of one of three colors R, G, and B is to be formed for each pixel so that the emissive layer of each color is formed, it is possible to evaporate materials of these colors by changing masks having a different opening position for each material. It is also possible to transport the substrate 14 into another vacuum chamber 10, in which a material is evaporated using a mask with a different opening position. Alternatively, for evaporation, the substrate 14, rather than the crucible 18, may be moved.

A heater 20 is attached to the peripheral surface of the crucible 18, and a heater power source section 24 is connected, via a cable 22, to the heater 20. Consequently, the heating state of the heater 20 is controlled by electrical power supply to the heater 20 from the heater power source section 24, so that evaporation state of the material from the crucible 18 is controlled.

According to the present embodiment, a plurality of pairs of transparent portions (windows) are provided at predetermined positions of the vacuum chamber 10, and a light emitting device 26 and a light receiving device 28 are disposed corresponding to each of these pairs. Light emitted from the light emitting device 26 transmits through a predetermined portion (i.e. a film thickness monitoring portion 52, as will be described below) of the substrate 14 on which the material layer is being formed and reaches the light receiving device 28.

Here, when the mask 50 is disposed between the substrate 14 and the crucible 18 as shown in FIG. 1, the mask 50 has an opening portion 54 for use in film thickness measurement which is formed on the path of light emitted from the light emitting device 26. In this case, it is preferable that the positions of the light emitting device 26 and the light receiving device 28 are made movable in accordance with the position of the opening portion 54 of the mask 50.

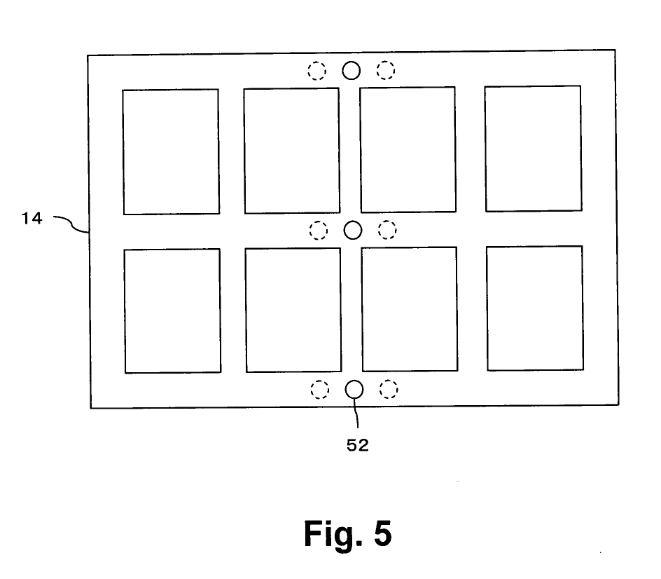

The evaporation material discharged from the crucible 18 passes through the film thickness measuring opening portion 54 on the mask 50 in the same manner as it passes through the opening portion of the mask 50 having a pattern corresponding to the pixel region. Consequently, in addition to the material layer having a desired pattern of pixel region or the like formed on the substrate, a film thickness (deposition thickness) monitoring portion 52 as shown FIG. 5 is simultaneously formed on the substrate 14 from the same material and under the same conditions as the material layer. The light emitted from the light emitting device 26 passes through the film thickness measuring opening portion 54 and also through the film thickness monitoring portion 52 on the substrate 14 and reaches the light receiving device 28. The light receiving device 28 supplies a signal indicative of the intensity of the received light to a controller 30, which then calculates the absorption intensity. Based on the absorption intensity, the controller 30 can calculate the thickness of the evaporation film by referring to the measurement data which has been previously obtained, as will be described below. The controller 30 then controls the heater power source section 24 to control supply of electric current from the heater power source section 24 to the heater 20 so that the evaporation film has an appropriate thickness. The controller 30 also controls the motor 40 to control the transporting rate of the crucible 18. In this manner, the deposition rate (the film formation rate) of a material on a substrate is controlled such that the material layer has a thickness of an optimal value.

Here, the light emitted from the light emitting device 26 can be ultraviolet rays, for example, and may be light having a wavelength of 200 nm to 900 nm or X rays. Alternatively, light of a single wavelength or white light may be adopted. Further, the wavelength of the light emitted from the light emitting device 26 may be varied within the above-described range of 200 nm to 900 nm and the light receiving device 28 may receive light having various wavelengths, whereby the wavelength at which absorption is caused is detected from the absorption spectrum to thereby specify the film thickness. In addition, the fluorescence spectrum or the like, rather than absorption, may be detected. In particular, in the case of measurement of a thickness of an emissive layer including an emissive material, effective detection of the film thickness can be achieved by measurement of the intensity of fluorescent light.

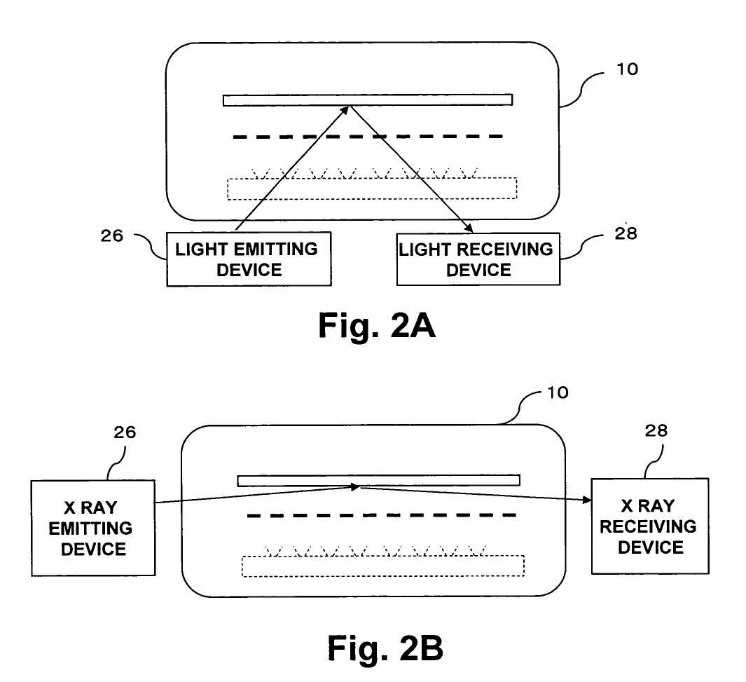

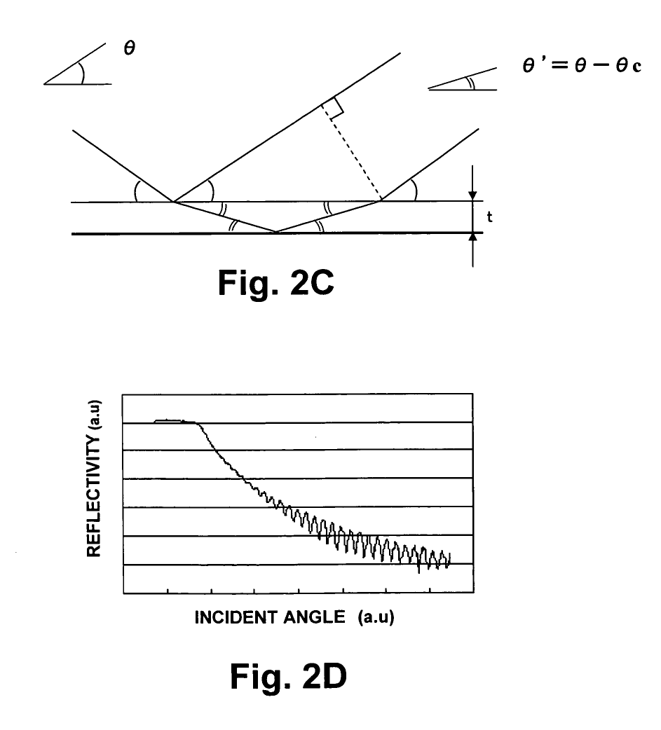

Further, when measuring fluorescent light, the light receiving device 28 may be disposed at a position where it can receive light conveyed (i.e. light exiting or traveling) from the portion onto which the light has been irradiated (i.e. reflected light), rather than transmitted light. In this case, both the light emitting device 26 and the light receiving device 28 are provided on the film surface side to be formed on the substrate 14 (i.e. on the side of the evaporation source), as shown in FIG. 2A. In the example shown in FIG. 2A, as the crucible 18 serving as an evaporation source is disposed below the substrate within the vacuum chamber 10, the light emitting device 26 and the light receiving device 28 are disposed further below the vacuum chamber 10. With this structure, light emitted from the light emitting device 26 is irradiated onto the film surface which is a measuring object (monitoring portion 52) and the light reflected from the film surface is received by the light receiving device 28, whereby the fluorescence intensity of the received light can be measured to calculate the film thickness.

When X rays are used for the light source, the light emitting device 26 is an X ray emitting device and the light receiving device 28 is a scintillator for measuring the intensity of the X ray, for example. As in the example shown in FIG. 2A, both the light emitting device 26 and the light receiving device 28 are provided on the film surface side to be formed on the substrate 14 (i.e. on the side of the evaporation source). In this case, however, the light emitting device 26 is disposed at a position which allows the light emitted therefrom to enter the material layer forming surface at a large incident angle (e.g. approximately 0.2 to 6 degrees with respect to the surface) such that the incident X ray achieves total internal reflection on the measurement object surface (monitor region) and the light receiving device 28 is disposed at a position where the light receiving device 28 can detect the X ray which is reflected on the measurement object surface (the monitor region) at a large exit angle similar to the incident angle, as shown in FIG. 2B.

As a specific technique of the film thickness measurement using X rays, a Grazing Incidence X-ray Reflectivity (GIXR) technique maybe adopted, and a principle in which the intensity of reflection waves is detected while changing the incident angles and the reflectivity (the reflection rate) is calculated from the intensity of reflection waves, and then the thickness of a material layer is calculated from the oscillation (change) period of the reflectivity which corresponds to the thickness of the material layer, is used. As there is an optical-path difference between the X ray reflected on the surface of the material layer (the monitor portion 52) and the X ray reflected on the boundary between the material layer (e.g. the monitor portion 52) and the lower layer (e.g. a substrate) as shown in FIG. 2C, the reflection waves interfere with each other. This optical-path difference is caused depending on the thickness t of the measurement object film and the angle θ′ (θ′=θ−θc) which corresponds to a difference between the incident angle θ of X ray and the critical angle of total reflection θc, namely the incident angle and the exit angle with respect to the measurement object film (the layer of the monitor portion 52) and the incident angle and the exit angle with respect to the boundary between the measurement object film and the lower layer. When the reflectivity is measured by the detector for X ray reflectivity measurement (the light receiving device 28), with the incident angle being varied, an oscillation structure (a change structure) due to interference as shown in FIG. 2D is generated in the measured reflectivity. It is therefore possible to calculate the thickness of the material layer from the oscillation period. Here, because the oscillation period decreases as the film thickness increases, it is possible to quantitatively obtain the film thickness from reflectivity using Fourier analysis, for example.

The light emitting device 26 and the light receiving device 28 as described above may be provided within the vacuum chamber 10. In this case, it is preferable to provide a shutter so as to prevent undesired deposition of evaporation materials on the light emitting device 26 and the light receiving device 28. Alternatively, rather than providing the shutter, it is also preferable to control the temperature at least around the light receiving device 28 (e.g. to increase the temperature to achieve a given high temperature) so as to prevent an evaporation material from adhering to the light receiving device 28.

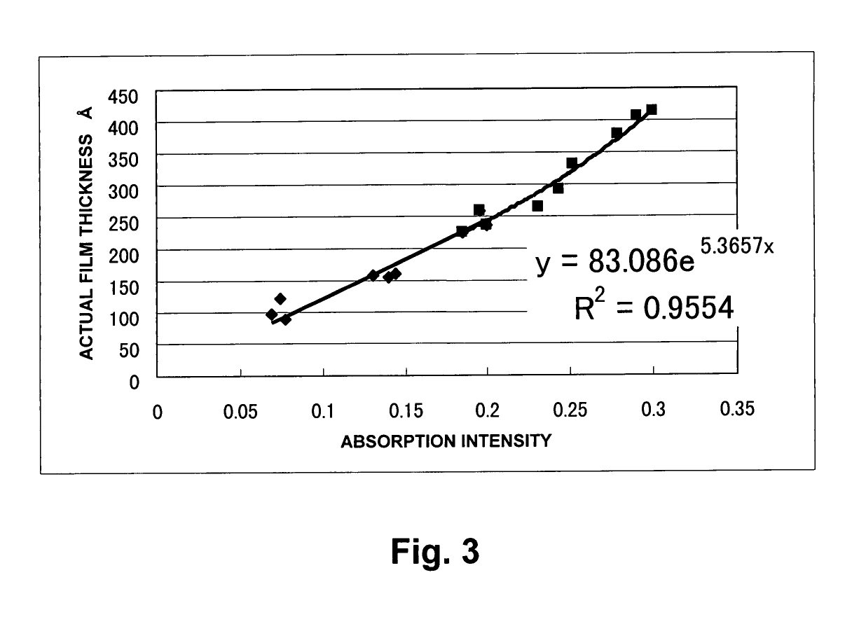

With regard to a CuPc (copper phthalocyanine) film which was actually obtained on a substrate by evaporation, FIG. 3 shows a result of comparison between the absorption intensity of the CuPc film with respect to ultraviolet rays (UV) used as a light source in the present embodiment and the thickness of the CuPc film measured by a contact-type step measuring device. As can be seen from the graph of FIG. 3, a very preferable correlation could be obtained between them. Specifically, when the actual film thickness obtained by the contact-type step measuring device is y and the absorption intensity is x, the relational expression of y=83.086 exp [5.3657x] can be obtained, and their dispersion of R²=0.9554 which is very close to 1 can also be obtained. This proves that the absorption intensity as in the present embodiment can provide accurate measurement of film thickness.

The relationship between the film thickness which was actually measured and the absorption intensity is shown in Table 1 below.

TABLE 1

| ACTUAL FILM THICKNESS Å | ABSORPTION INTENSITY |
|---|---|
| 88 | 0.07688 |
| 97 | 0.06862 |
| 123.5 | 0.07416 |
| 160.5 | 0.1446 |
| 158.5 | 0.13109 |
| 156 | 0.14001 |
| 236.5 | 0.19966 |
| 224 | 0.18444 |
| 258 | 0.19501 |
| 329.5 | 0.25211 |
| 265 | 0.2311 |
| 290.5 | 0.2439 |
| 415 | 0.29963 |
| 379 | 0.27865 |
| 406 | 0.29092 |

As described above, with the measurement of absorption intensity according to the present embodiment, it is possible to measure the thickness of a film based on the absorption intensity, which can be a replacement for spectroscopic ellipsometers which have been heretofore used for the film thickness measurement.

Table 2 below shows the result of comparison of accuracy between the measurement using an ellisometer and the measurement using the absorption intensity. More specifically, each of sample CuPc films which were formed on a substrate under the same measurement conditions was measured five times by each of the two measurement methods, and a variation (%) expressed by the following expression (i), which was obtained from the average value, the maximum value (max), and the minimum value (min), and the average variation are shown in Table 2.
(max−min)/(max+min)÷(2×average value)×100 (i)

TABLE 2

VARIATION

| SAMPLE No. | ELLIPSOMETER | UV |
|---|---|---|
| 1 | 5.15 | 3.19 |
| 2 | 3.51 | 3.29 |
| 3 | 6.25 | 4.85 |
| 4 | 2.54 | 3.5 |
| 5 | 3.85 | 2.73 |
| 6 | 2.52 | 1.46 |
| 7 | 2.62 | 0.93 |
| 8 | 2.38 | 2.21 |
| 9 | 4.31 | 3.41 |
| 10 | 3.95 | 0.47 |
| 11 | 3.7 | 1.41 |
| 12 | 4.18 | 1.32 |
| 13 | 4.15 | 0.41 |
| VARTATION | 3.78 | 2.24 |
| AVERAGE | | |

As is clearly shown by Table 2, the variation in the measurement results of the absorption intensity is smaller than the measurement results of the ellipsometer. This proves that the measurement of absorption intensity according to the present embodiment has higher accuracy than the measurement obtained by the ellipsometer.

In organic EL elements, the thickness of an organic layer is regarded as one of the important factors for determining the light emission conditions in an emissive layer. It is therefore believed that demands for accuracy in the thickness of an organic layer will further increase so as to realize higher emission efficiency and emission control of higher accuracy. In this regard, the above-described CuPc film, for example, is often used as a hole injection layer provided between an anode and a hole transport layer. Although a CuPc film is usually of a very thin thickness of about 10 nm, it is similarly desired to control the thickness of such a very thin film with high accuracy. Accordingly, it is difficult to perform accurate measurement of such a film when a quartz oscillator which cannot provide sufficient stability after continuous use as described above is adopted.

In addition, because irregular reflection is likely to occur on the surface of the above-described CuPc film, thickness measurement using an ellipsometer is not suitable for such a film. According to the present embodiment, on the contrary, higher measurement accuracy than that of an ellipsometer can be obtained and also real-time thickness measurement can be performed. Further, materials of an organic layer in an organic EL element still have problems concerning durability. Accordingly, it is desired that after formation of a lower electrode (an anode or a cathode), each layer of the organic layer having a multi-layer structure which is to be formed by, for example, a vacuum evaporation method, be formed continuously without breaking the vacuum atmosphere, so as to reduce the possibility that contaminants will adhere to the film surface or the possibility that water content which accelerates deterioration of the organic layer will be exposed to oxygen or the like. Consequently, by measuring the thickness of a film formed within a vacuum evaporation chamber as needed as in the present embodiment, the necessity of taking the substrate out of the evaporation apparatus only for the purpose of thickness measurement as required in the measurement using an ellipsometer can be eliminated, and accurate control of the film thickness can be achieved. Here, an organic layer having a multi-layer structure of an organic EL element may have a layered structure in which, when an anode is a lower electrode located on the lower side and a cathode which is formed substantially integral with an electron injection layer is provided as the upper electrode, a hole injection layer, a hole transport layer, an emissive layer, and electron transport layer are sequentially formed in this order from the lower side, for example. In such a structure, it is possible to continuously form these layers while each layer is being controlled to have an optimum thickness.

While the thickness measurement using the absorption intensity has been described in the above example, it is acknowledged that measurement of an amount of fluorescent light caused by light irradiation can similarly provide similar operational effects of the material. For example, because an emissive layer of an organic EL element often includes an organic material which emits fluorescent light, the thickness of such a layer can be preferably measured by fluorescence measurement. With the florescence measurement, reliable and accurate thickness measurement can be performed real-time even with respect to a layer having a very low light transmissivity, such as a relatively thick layer, and a light shielding layer. Further, a measurement method in which reflectivity of X rays is calculated to measure the film thickness does not require a standard sample according to its measurement principle, and can therefore provide absolute analysis results. In addition, because long-time variation in the intensity of X rays emitted from the light emitting device 26 does not, in principle, affect the measurement results, a calibration operation is not required and real-time measurement of the thickness of a material layer can be performed easily and accurately.

In the normal evaporation process, the crucible 18 is first heated to a predetermined temperature to stabilize the evaporation conditions. The heating of the crucible 18 is performed by moving the crucible 18 to a standby position which is out of the region below the substrate 14, as shown in FIG. 1. It is preferable that, at this standby position, a quartz type thickness meter is disposed above the crucible 18 to detect the evaporation conditions.

Also, the substrate 14 is fixed onto the substrate fixing portion 12. The motor 40 is then driven to transport the crucible 18 at a predetermined rate for performing evaporation onto the lower surface of the substrate 14. Because the film thickness can be detected from the absorption intensity obtained by the light emitting device 26 and the light receiving device 28 as described above, it is possible to control the heating state of the heater 20 and the rotational speed the motor 40 for continuously achieving stable evaporation. Such control may be performed so as to prevent a variation in evaporation with respect to a single substrate 14 or a variation in evaporation with respect to a plurality of substrates 14.

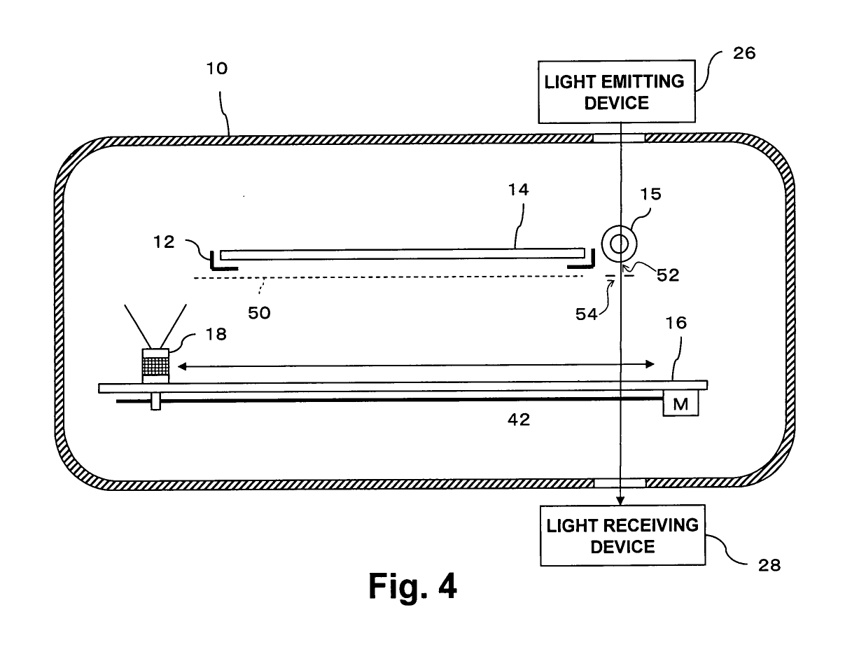

Further, while in the above embodiment the thickness of an evaporation film on the substrate 14 which is an actual evaporation object is detected, it is also possible to examine the evaporation state on a dummy substrate to thereby control the heating state of the crucible 18 and the transportation state of the crucible 18. In this case, the dummy substrate may be provided in place of the substrate 14 on which evaporation is to be actually performed or may be provided adjacent to the substrate 14. Further, as shown in FIG. 4, the dummy substrate 15 need not be a flat plate and may have a column or polygonal cylinder shape. In this case, the circumferential position (or the circumferential surface) of the dummy substrate 15 is changed in accordance with a change of the crucible 18 for forming each of a plurality of evaporation films, and the deposition thickness of an evaporation film formed on the corresponding circumferential surface is detected using the absorption or fluorescence detection device as described above, whereby the evaporation state of the evaporation material supplied from the crucible 18 can be detected, based on which an evaporation amount can be controlled. In particular, it is preferable to appropriately rotate a dummy substrate having a cylindrical shape to perform evaporation onto the surface thereof and detect the film thickness as described above.

FIG. 5 shows setting of the monitoring region (the film thickness measuring section) 52 on the substrate 14. In the shown example, three monitoring regions are provided in the width direction of the substrate 14 (which corresponds to the longitudinal direction of the crucible 18) and the monitoring portions (the monitoring layers) 52 are respectively formed at the monitoring regions. These monitoring portions 52 are set in a region on the substrate 14 which is not used for the actual organic EL element region (or for the display region). In the present embodiment, the crucible 18, which is of an elongated shape extending in the width direction of the substrate, moves in the direction which is orthogonal to the longitudinal direction of the crucible 18 (which corresponds to the width direction of the substrate 14). Accordingly, by providing three monitoring regions along the longitudinal direction of the crucible 18, uniformity of the evaporation amount in the longitudinal direction of the crucible 18 can be detected, and the heating state in the longitudinal direction of the crucible 18 can be further detected based on the detection result of the evaporation amount. The heating state can be controlled by disposing a plurality of the heaters 20 in the longitudinal direction of the crucible 18 and controlling energization of the individual heaters 20, for example.

Further, the film thickness monitoring portions 52 indicated by dotted line in FIG. 5 can be used for measuring the thickness of different evaporation films formed using different evaporation sources, when evaporation of multiple layers is performed continuously without breaking a vacuum atmosphere. More specifically, when masks having opening portions at different positions for forming the monitoring portions (film) 52 are used as the film forming mask 50 for forming different films, these monitoring portions 52 are provided at different positions on the substrate and are not superposed on the organic layer which is already formed thereunder, so that reliable measurement of the thickness of a film which is formed can be achieved. In this case, an interval of approximately 10 mm, for example, between the opening portions for film thickness measurement would suffice. In addition, these masks having the opening portions for film thickness measurement at different positions may be used in different film forming chambers. With the above-described method, reliable thickness measurement can be similarly performed for each of the films continuously formed in layers. Here, the monitoring portions 52 may be disposed such that they are dispersed over the entire region of the substrate 14 (though the region where the organic EL element is not formed is desirable).

While in the above example the crucible 18 having an elongated shape is used, a number of dot-like crucibles may be disposed. With these dot-like crucibles 18, evaporation onto the substrate 14 having a large area can be performed without the need for moving either the substrate 14 or the crucibles 18. On the other hand, it is likely that a variation in the thickness of an evaporation film is caused by evaporation with respect to a large area as described above. According to the present embodiment, however, by adopting a structure in which detection of the film thickness is performed at a plurality of positions dispersed on the substrate and the heating state of the crucibles 18 is partially controlled, it is possible to achieve control such that uniform evaporation can be performed as a whole. When the substrate 14 which is an evaporation object has a small area, a single dot-like crucible 18 may be used. Further, when the detected film thickness deviates from the target value by approximately ±50%, only the heating control of the crucibles 18 is not often sufficient, and it is therefore desirable to change the relative speed between the substrate 14 and the crucibles 18 (for example, the scanning speed of the crucible 18).

Further, it is possible to prevent deposition of an evaporation material onto the windows or the like which are provided corresponding to the light emitting device 26 and the light receiving device 28, respectively, by heating these windows to a high temperature. Even when the light emitting device 26 and the light receiving device 28 are provided within the vacuum chamber 10, it is preferable to heat a portion of the detectors where deposition of an evaporation material is not desirable to a high temperature to thereby prevent the deposition.

In the above examples, a horizontal type evaporation apparatus in which, as shown in FIG. 1, the crucible 18 is disposed at the lower portion and the mask 50 and the substrate 14 are disposed above the crucible 18 such that the direction of their planes corresponds to the horizontal direction is described. The present invention, however, is not limited to such a structure, and real-time film thickness measurement can similarly be performed in a vertical type deposition apparatus (a vacuum evaporation or sputtering apparatus). When the vertical type deposition apparatus is used, the film forming chamber of the deposition apparatus includes a window through which light emitted from the light emitting device 26 is transmitted and a window through which the light which is emitted from the light emitting device 26 and transmits through the substrate and the film is further transmitted to reach the light receiving device, so that the film thickness can be measured from the absorption intensity or a fluorescence amount. In the case of measurement of reflectivity, in the vertical-type deposition apparatus, the light emitting device 26 and the light receiving device 28 are disposed on the side of the substrate where a material layer is to be formed as shown in FIGS. 2A and 2B, and a window through which light rays such as UV rays, visible light or X rays transmit is provided in the film forming chamber.

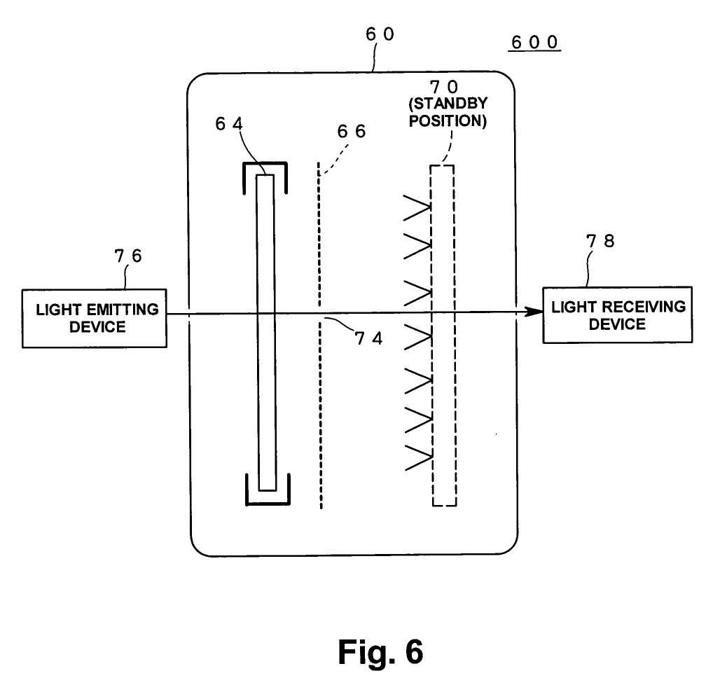

FIG. 6 is an example structure of such a vertical-type deposition apparatus 600. The deposition apparatus 600 is similar to the film forming apparatus shown in FIG. 1 with regard to its principle, and differs from it in that a substrate 64 and an evaporation source 70 are supported in the vertical direction. More specifically, the substrate 64 on which a film is to be formed is supported upright in the vertical direction within the film forming chamber. Further, a linear evaporation source 70 having a width which is substantially the same as that of the substrate is supported in the vertical direction. In the example structure shown in FIG. 6, the evaporation source 70, for example, is moved to change the relative position between the evaporation source 70 and the substrate 64, so that a material supplied from the evaporation source 70 adheres to the substrate 64 directly or via a mask 66. An opening portion 74 used for film thickness measurement is provided in the region of the mask 66 corresponding to the region on the substrate 64 where the organic EL element is not formed. By irradiating light emitted from the light emitting device 76 onto a film which is formed on the substrate 64 by evaporating a material from the evaporation source 70 through this opening portion 74 and measuring the transmitted light or fluorescent light by the light receiving device 78, the thickness of the film can be measured within the apparatus accurately and immediately after the film is formed. In the structure shown in FIG. 6, when the evaporation source 70 is situated at a standby position, for example, the light emitted from the light emitting device 76 is transmitted through the substrate 64 and the mask 66 and then enters the light receiving device 78 without being blocked by the evaporation source 70, although the evaporation source 70 is shown overlapping with the light from the light emitting device 76 in FIG. 6. Here, because the substrate 64 is supported upright in the vertical-type deposition apparatus 600, it is preferable to cause the light emitted from the light emitting device 76 to enter the apparatus from the side surface of the film forming chamber 60. For example, an optical fiber may be used to introduce the light into the film forming chamber 60.

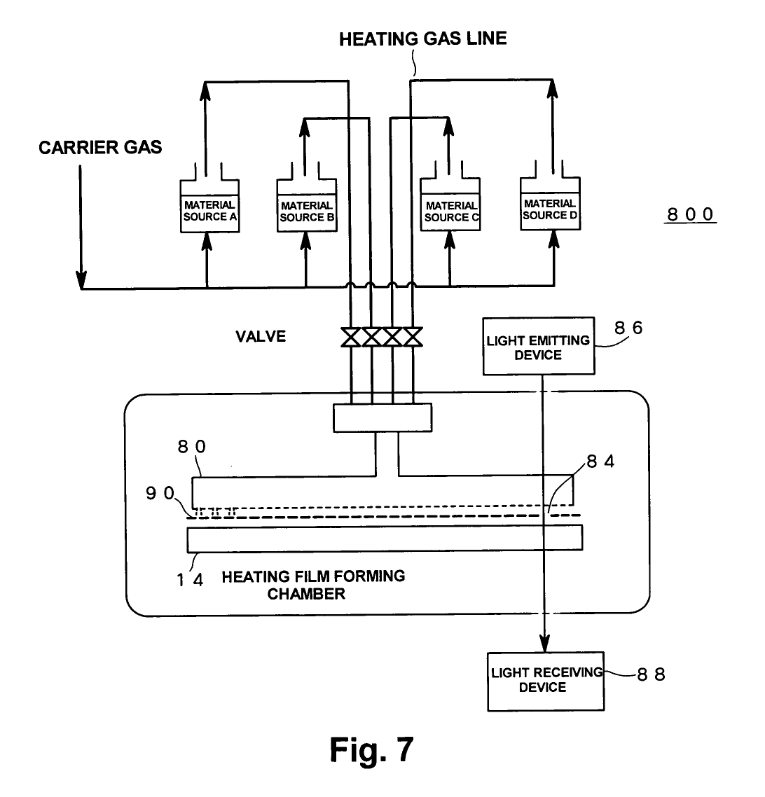

Further, the method of measuring a film thickness as described above can be similarly adopted in a vapor deposition type film forming apparatus 800. In this type of film forming apparatus in which a shower nozzle 80 is used as a discharging end of the evaporation source as shown in FIG. 7, a film forming material (e.g. an organic material) is sequentially evaporated into a carrier gas in the order of films to be formed and the material is selectively supplied through the heating gas line via a valve and is discharge from the nozzle 80 onto the substrate 14 which is held within the heating film forming chamber to form layered films. With this structure, an opening portion 84 for use in film thickness measurement is formed on the mask 90 which is disposed between the substrate 14 and the nozzle 80, for example, whereby the thickness of a film formed at a portion corresponding to the opening portion can be accurately measured by detecting the absorption intensity or fluorescence intensity by the light emitting device 86 and the light receiving device 88. Further, real-time measurement of the thickness of each thin film which is continuously formed can be performed, for example, by changing the position of the opening portion 84 used for film thickness measurement on the mask 90 by means of a shutter each time the evaporation source is changed or by using different masks.

While the preferred embodiments of the present invention have been described using specific terms, such description is for illustrative purposes only, and it is to be understood that changes and variations may be made without departing from the spirit or scope of the appended claims.

1. A method of measuring a deposition thickness of a material layer which is deposited on a substrate, comprising the steps of:
depositing a material onto a substrate and a deposition thickness monitoring region provided at a predetermined position on or near the substrate to form a material layer;
irradiating predetermined light onto the deposition thickness monitoring region and detecting light conveyed from the material layer at the deposition thickness monitoring region; and
measuring the deposition thickness of the material layer formed on the substrate based on the intensity of the light which is detected.

2. A method of measuring a deposition thickness of a material layer which is deposited on a substrate,
wherein the deposition thickness of the material layer is obtained by detecting the absorption intensity, the fluorescence intensity, or the reflection intensity, based on the light conveyed from the deposition thickness monitoring region.

3. A method of forming a material layer on a substrate, comprising the steps of:
depositing a material onto a substrate and a deposition thickness monitoring region provided at a predetermined position on or near the substrate to form a material layer;
irradiating predetermined light onto the deposition thickness monitoring region and detecting light conveyed from the material layer at the deposition thickness monitoring region; and
measuring the deposition thickness of the material layer formed on the substrate based on the intensity of the light which is detected and controlling a deposition rate of the material in accordance with the measurement result.

4. A method of forming a material layer according to claim 3, wherein
the depositing of the material is performed by an evaporation method in which the material in an evaporation source is heated and evaporated to be deposited on the substrate, and
at least one of a heating state of the material and a relative scanning rate of the evaporation source and the substrate is controlled to control the deposition rate.

5. A method of forming a material layer according to claim 4, wherein
a plurality of deposition thickness monitoring regions are provided on the substrate or near the substrate such that they are separate from each other, and
heating distribution of the evaporation source is controlled based on the deposition thickness at each deposition thickness monitoring region.

6. A method of forming a material layer according to claim 4, wherein
an evaporation chamber in which the material layer is formed by evaporation on the substrate includes window portions on an optical path of light which is emitted from a light emitting device disposed outside the evaporation chamber and reaches the deposition thickness monitoring region and on an optical path of light which is conveyed from the material layer and reaches a light receiving device, respectively, the respective window portions allowing transmission of the light, and
the window portions are heated while the material layer is being evaporated.

7. A method of forming a material layer according to claim 3, wherein
the deposition thickness of the material layer is obtained by detecting the absorption intensity, the fluorescence intensity, or the reflection intensity, based on the light conveyed from the deposition thickness monitoring region.

8. A deposition thickness measuring apparatus for detecting a deposition thickness of a material layer formed on a substrate, comprising:
a light irradiation device for irradiating predetermined light onto a deposition thickness monitoring region provided at a predetermined position on or near a substrate on which a material layer is deposited; and
a light detecting device for detecting the intensity of light conveyed from the deposition thickness monitoring region onto which light is irradiated,
wherein the deposition thickness of the material layer formed on the substrate is measured based on the intensity of light detected by the light detecting device.

9. A forming apparatus for forming a material layer by deposition on a substrate, comprising:
a light irradiation device for irradiating predetermined light onto a deposition thickness monitoring region provided at a predetermined position on or near a substrate on which a material layer is deposited;
a light detecting device for detecting the intensity of light transmitted from the deposition thickness monitoring region onto which light is irradiated; and
a deposition rate controller for measuring the deposition thickness of the material layer based on the intensity of light detected by the light detecting device and adjusting a deposition rate based on the result of measurement of the deposition thickness.

10. A forming apparatus according to claim 9, wherein
the deposition of the material is performed by an evaporation method in which the material in an evaporation source is heated and evaporated to be deposited on the substrate, and
at least one of a heating state of the material and a relative scanning rate of the evaporation source and the substrate is controlled to control the deposition rate.

11. A forming apparatus according to claim 10, wherein
a plurality of deposition thickness monitoring regions are formed on the substrate or near the substrate such that they are separate from each other, and
heating distribution of the evaporation source is controlled based on the deposition thickness at each deposition thickness monitoring region.

12. A forming apparatus according to claim 10, wherein
an evaporation chamber in which the material layer is formed by evaporation on the substrate includes window portions on an optical path of light which is emitted from a light emitting device disposed outside the evaporation chamber and reaches the deposition thickness monitoring region and on an optical path of light which is transmitted from the material layer and reaches a light receiving device, respectively, the respective window portions allowing transmission of the light,
the apparatus further comprising a heating section for heating the window portions.

13. A method of measuring a deposition thickness of a material layer on a substrate, comprising the steps of:
depositing a material onto a substrate and a deposition thickness monitoring region provided at a predetermined position on or near the substrate to form a material layer,
irradiating ultraviolet rays or light rays having a wavelength ranging from 200 nm to 900 nm onto the deposition thickness monitoring region and detecting light transmitted from the material layer at the deposition thickness monitoring region, and
measuring the deposition thickness of the material layer formed on the substrate based on the intensity of the light which is detected.

14. A method of measuring a deposition thickness of a material layer on a substrate, comprising the steps of:
depositing a material onto a substrate and a deposition thickness monitoring region provided at a predetermined position on or near the substrate to form a material layer,
irradiating an X ray onto the deposition thickness monitoring region and detecting X ray reflection wave from the material layer at the deposition thickness monitoring region, and
measuring the deposition thickness of the material layer formed on the substrate based on the X ray reflection wave which is detected.

15. A method of measuring a deposition thickness of a material layer on a substrate according to claim 14, wherein
the deposition thickness of the material layer is calculated based on a change of the reflection rate of the X ray reflection wave which is detected, the change being caused by interference.
